(19) United States
(12) Patent Application Publication
(10) Pub. No.: US 2015/0357436 A1
(43) Pub. Date: Dec. 10, 2015

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Wen-Jiun Shen, Yunlin County (TW); Chia-Jong Liu, Ping-Tung County (TW); Yi-Wei Chen, Taichung City (TW); Ssu-I Fu, Kaohsiung City (TW); Chung-Fu Chang, Tainan City (TW); Yu-Hsiang Hung, Tainan City (TW); Yen-Liang Wu, Taipei City (TW); Man-Ling Lu, Taoyuan County (TW)

(21) Appl. No.: 14/324,252

(22) Filed: Jul. 7, 2014

(30) Foreign Application Priority Data
Jun. 10, 2014 (CN) 201410254365.7

(51) Int. Cl. H01L 29/66; H01L 21/3065; H01L 29/78

(52) U.S. Cl. CPC H01L 29/66636; H01L 29/7848; H01L 21/3065

(57) ABSTRACT

A method for fabricating semiconductor device is disclosed. The method includes the steps of: providing a substrate; forming a gate structure on the substrate; performing a first dry etching process to form a recess in the substrate adjacent to the gate structure; and performing a second dry etching process to expand the recess.

### BACKGROUND OF THE INVENTION

1. Field of the Invention

The invention relates to a method for fabricating semiconductor device, and more particularly, to a method of conducting two dry etching processes for forming a circular recess in the substrate adjacent to two sides of a gate structure.

2. Description of the Prior Art

In order to increase the carrier mobility of semiconductor structure, it has been widely used to apply tensile stress or compressive stress to a gate channel. For instance, if a compressive stress were to be applied, it has been common in the conventional art to use selective epitaxial growth (SEG) technique to form epitaxial structure such as silicon germanium (SiGe) epitaxial layer in a silicon substrate. As the lattice constant of the SiGe epitaxial layer is greater than the lattice constant of the silicon substrate thereby producing stress to the channel region of PMOS transistor, the carrier mobility is increased in the channel region and speed of MOS transistor is improved accordingly. Conversely, silicon carbide (SiC) epitaxial layer could be formed in silicon substrate to produce tensile stress for gate channel of NMOS transistor.

Despite the aforementioned approach improves the carrier mobility in the channel region, the complexity of the overall process also increases accordingly. For instance, conventional approach typically forms a recess in the silicon substrate, deposits a buffer layer in the recess and then forms an epitaxial layer thereafter. Nevertheless, the buffer layer formed by this approach typically has uneven thickness, such that in most cases the bottom portion of the buffer layer is approximately three to five times thicker than the sidewall portion of the buffer layer. This causes negative impacts such as short channel effect or drain induced barrier lowering (DIBL) and degrades the quality and performance of the device.

### SUMMARY OF THE INVENTION

It is therefore an objective of the present invention to provide a semiconductor device and fabrication method thereof to resolve the aforementioned issues.

According to a preferred embodiment of the present invention, a method for fabricating semiconductor device is disclosed. The method includes the steps of: providing a substrate; forming a gate structure on the substrate; performing a first dry etching process to form a recess in the substrate adjacent to the gate structure; and performing a second dry etching process to expand the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating semiconductor device according to a preferred embodiment of the present invention.

### DETAILED DESCRIPTION

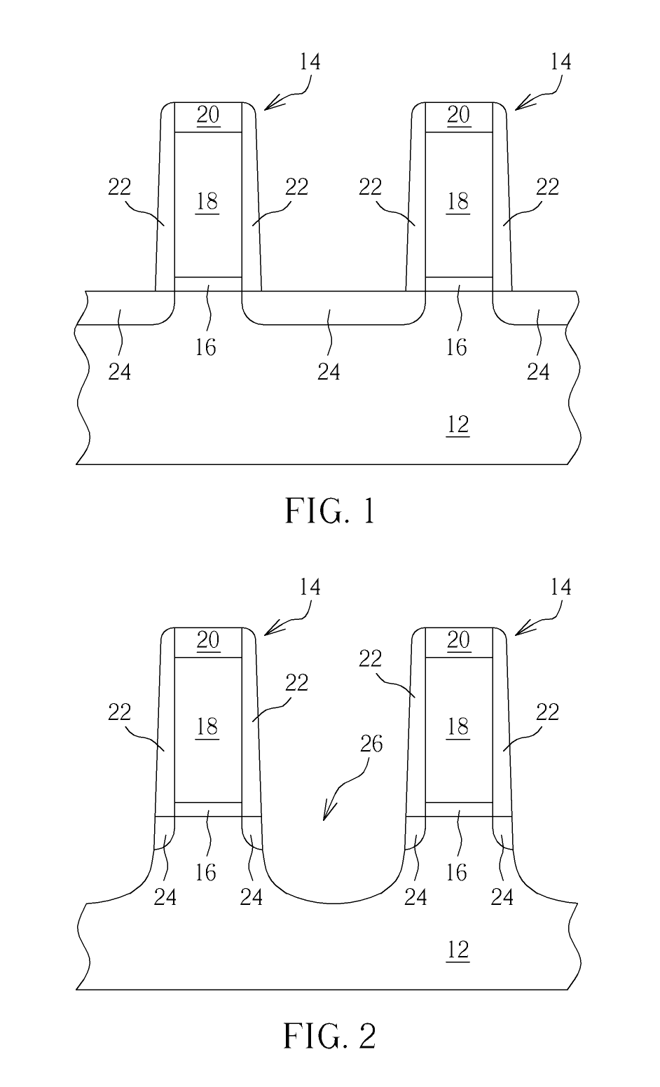

Referring to FIGS. 1-5, FIGS. 1-5 illustrate a method for fabricating semiconductor device according to a preferred embodiment of the present invention. As shown in FIG. 1, a substrate 12 is first provided, and at least one gate structure 14 is formed on the substrate 12. In this embodiment, the formation of the gate structure 14 could be accomplished by sequentially forming a gate dielectric layer, a gate material layer, and a hard mask on the substrate 12, conducting a pattern transfer process by using a patterned resist (not shown) as mask to partially remove the hard mask, gate material layer, and gate dielectric layer through single or multiple etching processes, and stripping the patterned resist for forming at least one gate structure 14 on the substrate 12. Preferably, each gate structure 14 is composed of a patterned gate dielectric layer 16, a patterned gate material layer 18, and a patterned hard mask 20 and despite two gate structures 14 are disclosed in this embodiment, the quantity of the gate structure 14 is not limited two.

According to an embodiment of the present invention, the substrate 12 could be a semiconductor substrate including silicon substrate, epitaxial substrate, silicon carbide substrate, or silicon-on-insulator (SOI) substrate, but not limited thereto. The gate dielectric layer 16 could composed of silicon dioxide (SiO₂), silicon nitride, or high dielectric constant material. The gate material layer 18 could be composed of conductive material such as metal, polysilicon, or silicides. The hard mask 20 could be composed of silicon dioxide, silicon nitride, silicon carbide, or silicon oxynitride, but not limited thereto. Moreover, the hard mask 20 could further include a first hard mask and a second hard mask, in which each of them could include silicon oxide and silicon nitride, which is within the scope of the present invention.

According to an embodiment of the present invention, a plurality of doped wells (not shown) or a plurality of shallow trench isolations (STIs) could also be formed in the substrate 12. Also, it should be noted that even though the fabrication process of this embodiment is applied to a planar type transistor, the fabrication process could also be applied to non-planar transistor such as FinFET, and in such instance, the element 12 would become a fin-shaped structure on a substrate.

Next, a spacer, such as an offset spacer 22, is formed on the sidewall of each gate structure 14, and a lightly doped implantation process is selectively conducted and then using a rapid thermal anneal process of approximately 930° C. to activate the dopants implanted into the substrate 12. This forms a lightly doped drain 24 in the substrate 12 adjacent to two sides of the offset spacer 22.

Next, as shown in FIG. 2, a first dry etching process is conducted by using the gate structure 14 and offset spacer 22 as mask to etch the substrate 12 along the offset spacer 22 for forming a recess 26 in the substrate 12 adjacent to each of the gate structures 14.

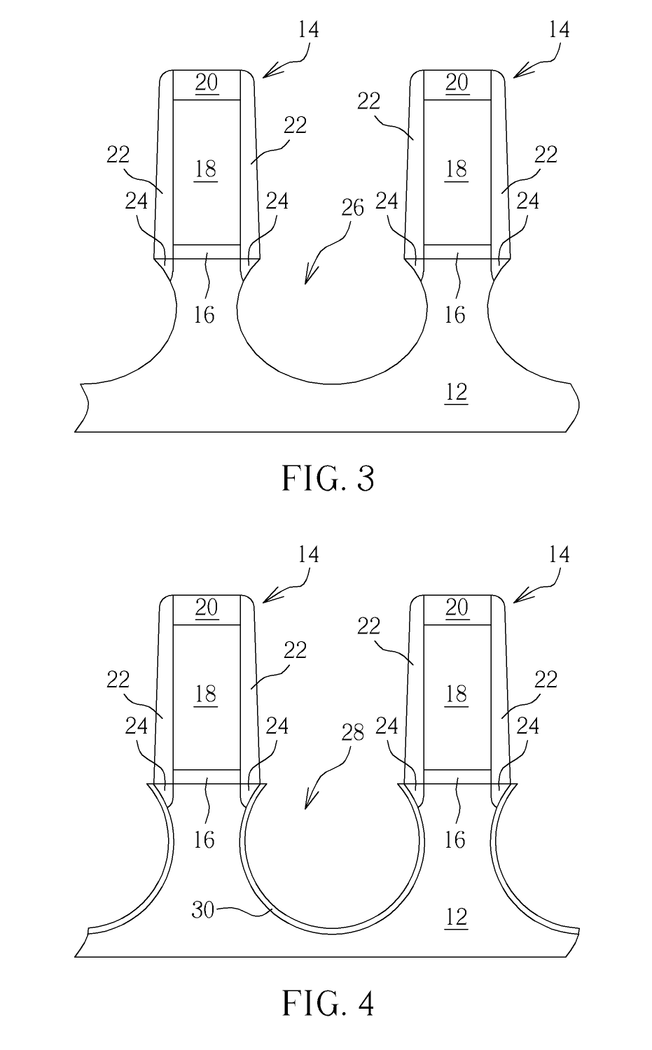

Next, as shown FIG. 3, a second dry etching process is conducted to further etch the recess 26 formed by the aforementioned first dry etching process. The second dry etching process preferably etches the sidewall portion of the recess 26, such as lateral etching the substrate 12 directly under the offset spacer 22 to further expand the area of the recess 26.

According to a preferred embodiment of the present invention, the first dry etching process is conducted to vertically etch the recess 26, in which the bottom portion of the recess 26 reveals a slightly circular profile. The second dry etching process conducted thereafter could be accomplished by adjusting the bias power of the processing equipment, such as slightly lowering the bias power to expand the recess 26 by lateral etching. This approach ensures that the recess 26 will not be turned into diamond shaped or hexagonal (or sigma) shaped recess produced by conventional wet etching process, and after the recess 26 is expanded by the lateral etching of the second dry etching process, a substantially circular recess 28 or preferably a recess of perfect circle is formed in the substrate 12 adjacent to the gate structure 14, as shown in FIG. 4.

It should be noted that even though two dry etching processes are conducted to form a recess 28 of perfect circle in this embodiment, the quantity of dry etching process is not limited to two. Instead, the quantity of the dry etching process could be adjusted depending on the demand of the process and result of the etching process until the recess 26 expands from a slightly rectangular shape from the beginning to a perfect circle, which is also within the scope of the present invention.

After the recess 28 is formed, a pre-clean process is selectively conducted by using cleaning agent such as diluted hydrofluoric acid or SPM containing sulfuric acid, hydrogen peroxide, and deionized water to remove native oxide or other impurities from the surface of the recess 28, and a buffer layer 30 is formed in the recess 28 while covering the surface of the substrate 12 within the recess 28. In this embodiment, the buffer layer 30 includes silicon germanium, and as the buffer layer 30 is conformally grown on the surface of the circular substrate 12 within the recess 28, the buffer layer 30 preferably includes an even thickness.

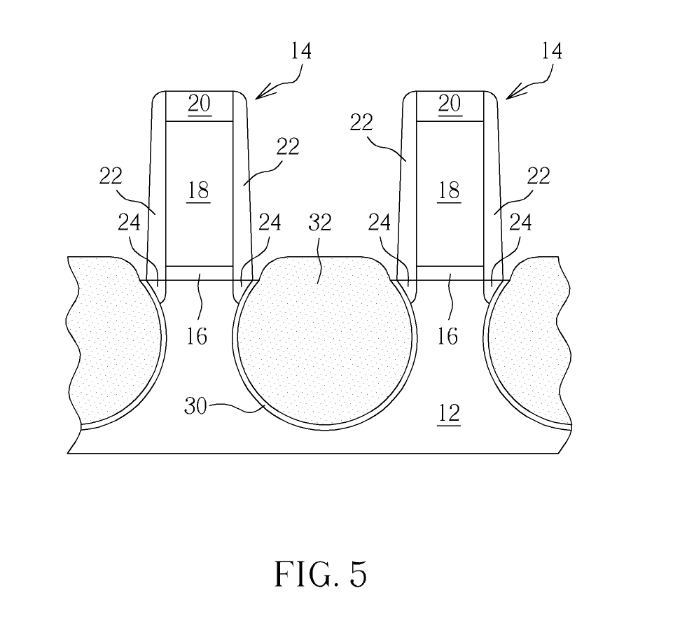

Next, as shown in FIG. 5, a selective epitaxial growth process is conducted to form an epitaxial layer 32 composed of silicon germanium on the buffer layer 30. In this embodiment, the germanium concentration of the buffer layer is substantially lower than the germanium concentration of the epitaxial layer 32, such that a buffering effect could be established between the surface of the recess 28 and the epitaxial layer 32 thereby reducing structural defect of the epitaxial layer 32. This completes the method for fabricating semiconductor device according to a preferred embodiment of the present invention.

As the semiconductor device of the aforementioned embodiment pertains to a PMOS transistor, the epitaxial layer 32 would preferably be composed of silicon germanium, but not limited thereto. Moreover, an in-situ epitaxial growth process accompanying p-type implantation could also be employed to form a silicon germanium structure with p-type dopants embedded therein, which could be serving as source/drain region directly so that additional ion implantation for forming source/drain region could be omitted. In other embodiments of the present invention, it would also be desirable to conduct epitaxial growth process through single-layer or multi-layer approach, and concentration gradient of germanium and/or p-type dopants could also be formed in an increasing manner, but not limited thereto.

Next, typical transistor fabrication process could be carried out by forming a main spacer on the sidewall of each gate structure 14, and then forming a source/drain region in the substrate 12 adjacent to two sides of the main spacer. Elements including silicides, contact etch stop layer (CESL), and interlayer dielectric (ILD) layer could be formed thereafter, and a replacement metal gate process could also be conducted to transform the gate structures 14 into metal gates. As these processes are well known to those skilled in the art, the details of which are not explained herein for the sake of brevity.

Overall, the present invention conducts two dry etching process after a gate structure is formed, in which the first dry etching process forms a recess in the substrate adjacent to at least one side of the gate structure while the follow-up second dry etching process further expands the recess formed through the first dry etching process. Specifically, the first dry etching process vertically etches the substrate to form a slightly rectangular recess with a slightly circular bottom profile. The second dry etching process then expands the recess by laterally etches the substrate and causes the recess to expand into a substantially circular shape.

As recess formed by conventional single dry etching approach or combination of dry etching and wet etching could never produce a perfect circular recess so that buffer layer deposited in the recess could not have an even thickness, the present invention resolves this issue by conducting two dry etching processes, preferably including the aforementioned vertical etching and lateral etching processes to form a recess in the substrate with perfect circular shape. By using this approach, the thickness of the buffer layer could be controlled and even thickness for the buffer layer could also be achieved.

It should further be noted that despite the aforementioned embodiments pertains to planar type transistors, the process of the present invention could also be applied to non-planar transistors such as FinFETs, which is also within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a substrate;
forming a gate structure on the substrate;
performing a first dry etching process to form a recess in the substrate adjacent to the gate structure; and
performing a second dry etching process to expand the recess.

2. The method of claim 1, further comprising forming a spacer around the gate structure before performing the first dry etching process.

3. The method of claim 1, further comprising forming a buffer layer in the recess after performing the second dry etching process.

4. The method of claim 3, wherein the buffer layer comprises silicon germanium.

5. The method of claim 3, wherein the buffer layer comprises an even thickness.

6. The method of claim 3, further comprising forming an epitaxial layer in the recess after forming the buffer layer.

7. The method of claim 6, wherein the germanium concentration of the buffer layer is lower than the germanium concentration of the epitaxial layer.

8. The method of claim 6, wherein the epitaxial layer comprises silicon germanium.

9. The method of claim 1, further comprising:
performing the first drying etching process for vertically etching the recess; and
performing the second dry etching process for laterally etching the recess.

10. The method of claim 9, further comprising adjusting the bias power of an equipment for performing the second dry etching process to expand the recess laterally.

11. The method of claim 1, wherein the shape of the recess comprises a perfect circle.

12. A semiconductor device, comprising:
a substrate;
a gate structure on the substrate; and
a recess adjacent to the gate structure, wherein the recess comprises a circular shape.

13. The semiconductor device of claim 12, further comprising a spacer around the gate structure.

14. The semiconductor device of claim 12, further comprising a buffer layer in the recess.

15. The semiconductor device of claim 14, wherein the buffer layer comprises silicon germanium.

16. The semiconductor device of claim 14, wherein the buffer layer comprises an even thickness.

17. The semiconductor device of claim 12, wherein the shape of the recess comprises a perfect circle.
